(19) United States
(12) Patent Application Publication
(10) Pub. No.: US 2008/0188026 A1
(43) Pub. Date: Aug. 7, 2008

(54) METHOD FOR MANUFACTURING A SEMICONDUCTOR PACKAGE STRUCTURE HAVING MICRO-ELECTRO-MECHANICAL SYSTEMS

(75) Inventors: Meng-Jen Wang, Kaohsiung (TW); Hsueh-An Yang, Kaohsiung (TW)

Correspondence Address: VOLENTINE & WHITT PLLC, ONE FREEDOM SQUARE, 11951 FREEDOM DRIVE SUITE 1260, RESTON, VA, 20190, US

(73) Assignee: ADVANCED SEMICONDUCTOR ENGINEERING, INC., Kaohsiung (TW)

(21) Appl. No.: 12/023,274

(22) Filed: Jan. 31, 2008

(30) Foreign Application Priority Data
Feb. 1, 2007 (TW) 096103628

(51) Int. Cl. H01L 21/50

(52) U.S. Cl. 438/51; 257/E21.499

(57) ABSTRACT

The present invention relates to a method for manufacturing a semiconductor package structure having Micro-Electro-Mechanical Systems (MEMS). A plurality of Micro-Electro-Mechanical Systems is disposed on a plurality of substrate units of a substrate, and a plurality of cover units of a cover plate is used to seal the corresponding Micro-Electro-Mechanical Systems. Next, a body of the cover plate is removed, and the substrate is then cut, so as to form a plurality of semiconductor package structures. In doing so, the body is removed and the substrate is cut without patterning the cover plate and the substrate in advance to form aligning marks, such that the packaging process of the present invention is simpler. In addition, the cover plate is not limited to transparent material, so that various materials can be used in various applications. Furthermore, the body can be removed by using a simple grinding process, such that the manufacturing cost can be reduced.

### BACKGROUND OF THE INVENTION

1. Field of the Invention

The present invention relates to a method for manufacturing a semiconductor package structure, particularly to a method for manufacturing a semiconductor package structure having micro-electro-mechanical systems (MEMS).

2. Description of the Related Art

Referring to FIGS. 1 to 5, they are schematic views of a method for manufacturing a conventional semiconductor package structure having MEMS. Referring to FIG. 1, firstly, a substrate 11 is provided. The substrate 11 has a plurality of substrate units 111 (as shown by dashed lines), and each substrate unit 111 has a plurality of pads 112.

Referring to FIG. 2, a plurality of MEMS 12 is disposed on each substrate unit 111. Referring to FIG. 3, a cover plate 13 is provided. The cover plate 13 has a plurality of cover units 131 and a plurality of connection portions 132. The connection portions 132 are connected to the cover units 131, such that the cover units 131 are spaced apart by a certain distance. The cover units 131 are used to seal the corresponding MEMS 12, and the pads 112 of the substrate unit 111 are located outside of the cover unit 131. In this embodiment, the cover plate 13 is a transparent material, for example, a glass material or a silicon material.

Next, the cover plate 13 is cut to remove the connection portions 132 (the connection portions 132 may also be removed by using an etching process or a photolithography technique), as shown in FIG. 4. Referring to FIG. 5, finally, a cutting tool (not shown) is used to cut the substrate 11 according to the edge of the substrate units 111, so as to form a plurality of semiconductor package structures 1. Each semiconductor package structure 1 has a substrate unit 111, a MEMS 12, and a cover unit 131. The semiconductor package structure 1 is the conventional semiconductor package structure having MEMS.

In the conventional manufacturing method, the cover plate 13 and the substrate 11 must be patterned in advance, so as to form aligning marks. The cover plate 13 must be a transparent material, such that the cover units 131 are disposed on the corresponding substrate units 111 according to the marks. Then, the cover plate 13 is cut according to the marks of the cover plate 13, so as to remove the connection portions 132. Then, the substrate 11 is cut according to the marks of the substrate 11, so as to form the plurality of semiconductor package structures 1.

In the conventional manufacturing method, the aligning marks must be formed on the cover plate 13 and the substrate 11, and thus an additional packaging step is added. Furthermore, if the photolithography technique is adopted to remove the connection portions 132, it is more difficult for the process to be performed, and accordingly, the manufacturing cost is increased.

Consequently, there is an existing need for providing a method for manufacturing a semiconductor package structure having MEMS to solve the above-mentioned problems.

### SUMMARY OF THE INVENTION

The present invention is directed to a method for manufacturing a semiconductor package structure having MEMS, which comprises the following steps: (a) providing a substrate having a plurality of substrate units, wherein each substrate unit has a plurality of pads; (b) disposing a plurality of MEMS on each substrate unit; (c) disposing a cover plate on the substrate, wherein the cover plate has a body and a plurality of cover units, the cover units are disposed on a surface of the body, each cover unit seals the corresponding MEMS, and the pads of the substrate unit are located outside of the cover unit; (d) removing the body; and (e) cutting the substrate to form a plurality of semiconductor package structures, wherein each semiconductor package structure has the substrate unit, the MEMS, and the cover unit.

The present invention is further directed to a method for manufacturing a semiconductor package structure having MEMS, which comprises the following steps: (a) providing a substrate having a plurality of substrate units, wherein each substrate unit has a plurality of pads; (b) disposing a MEMS on each substrate unit; (c) disposing a cover plate on the substrate, wherein the cover plate has a plurality of first recesses and a plurality of second recesses, the first recesses are used to seal the corresponding MEMS, the second recesses are corresponding to the pads of the substrate unit, the first recess has a first depth, the second recess has a second depth, and the first depth is smaller than the second depth; (d) removing a part of the cover plate, and keeping the MEMS being sealed in the first recesses and exposing the pads of the substrate unit; and (e) cutting the substrate to form a plurality of semiconductor package structures, wherein each semiconductor package structure has the substrate unit, the MEMS, and a part of the cover plate for defining the first recess.

The manufacturing method of the present invention uses a grinding process to remove the cover plate, so as to expose the pads of the substrate unit. Therefore, it is not necessary to pattern the cover plate and the substrate in advance for forming the aligning marks that serve as the reference for cutting the cover plate and the substrate. Thus, the packaging process of the present invention is simpler than the conventional packaging process. In addition, as for the manufacturing method of the present invention, it does not need to pattern the cover plate and the substrate in advance to form the aligning cutting marks. Therefore, the cover plate can be transparent material or non-transparent material, so that various materials can be used in various applications. Furthermore, the body can be removed by using the simple grinding process, such that the manufacturing method of the present invention is simpler and quicker, the manufacturing capacity is increased, and the manufacturing cost is reduced.

### BRIEF DESCRIPTION OF THE DRAWINGS

FIGS. 1 to 5 are schematic views of a conventional method for manufacturing a semiconductor package structure having MEMS;

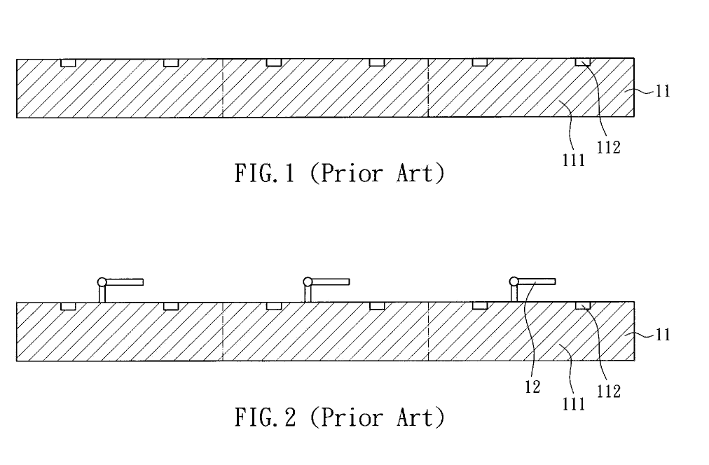

FIG. 6 is a schematic view of a substrate according to the present invention;

FIG. 7 is a schematic view of disposing a plurality of MEMS on the substrate according to the present invention;

FIG. 8 is a schematic view of disposing a cover plate on the substrate according to the present invention;

FIG. 9 is a schematic view of removing the body of the cover plate according to the present invention; and

FIG. 10 is a schematic view of a semiconductor package structure having MEMS according to the present invention.

### DETAILED DESCRIPTION OF THE INVENTION

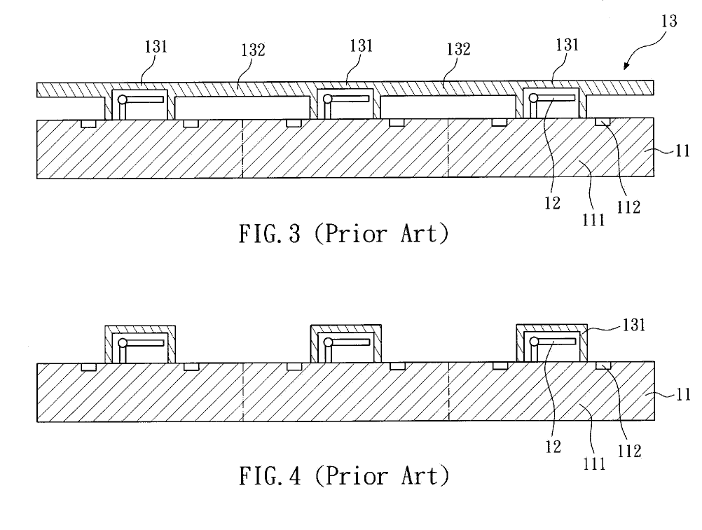

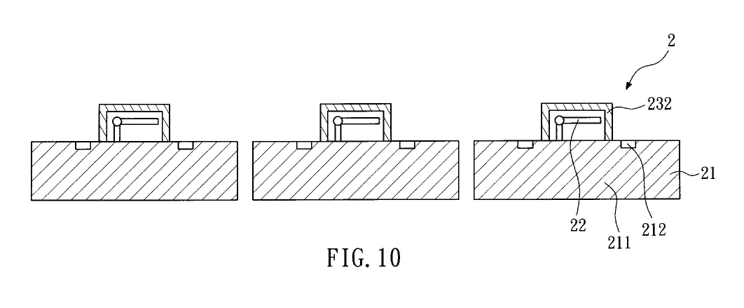

Referring to FIGS. 6 and 10, they are schematic views of a method for manufacturing a semiconductor package structure having MEMS according to the present invention. Firstly, referring to FIG. 6, a substrate 21, which has a plurality of substrate units 211 (as shown by dashed lines), is provided, and each substrate unit 211 has a plurality of pads 212. The substrate 21 may be a CMOS wafer.

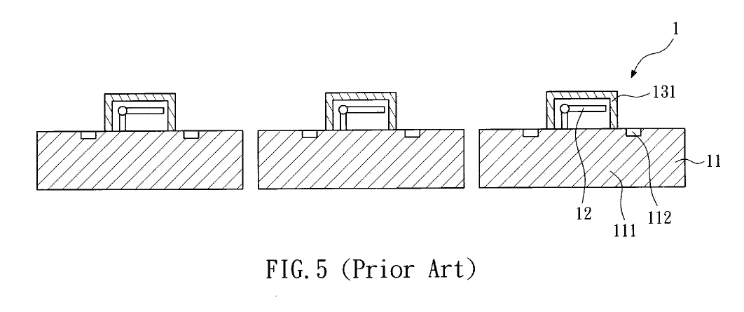

Referring to FIG. 7, a MEMS 22 is disposed on each substrate unit 211. In this embodiment, the MEMS 22 is an optical device. The MEMS 22 comprises at least a micro lens set 221, and each micro lens set 221 comprises a supporting component 222, a hinge 223 and a micro lens 224. The supporting component 222 has a first end 225 and a second end 226, in which the second end 226 of the supporting component 222 is located on the substrate unit 211. The hinge 223 is disposed on the first end 225 of the supporting component 222. One end of the micro lens 224 is connected to the hinge 223. The micro lens 224 of each micro lens set 221 rotates with to the hinge 223 as a center. It should be noted that the MEMS 22 is not limited to be an optical device, but can be other micro-electro-mechanical elements.

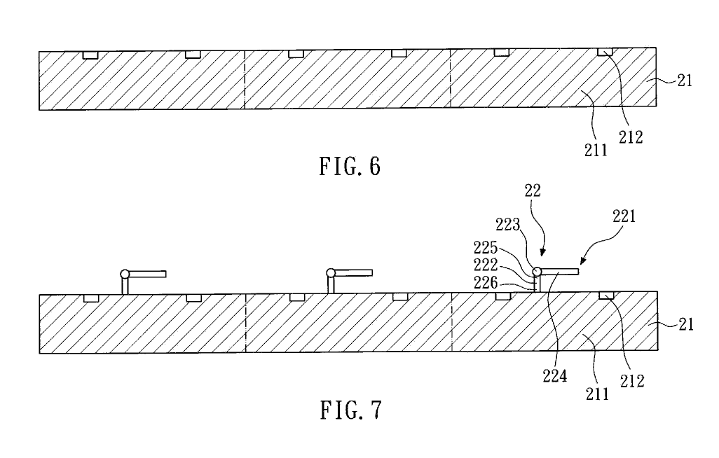

Referring to FIG. 8, a cover plate 23, which has a body 231 and a plurality of cover units 232 (defined by the dashed lines in the drawing), is provided. The cover units 232 are disposed on a surface of the body 231. The cover unit 232 has a first recess 233, and the neighboring cover units 232 define a second recess 234. The depth of the second recess 234 is greater than that of the first recess 233. Each cover unit 231 seals the corresponding MEMS 22, such that the pads 212 of the substrate unit 211 are located outside of the cover unit 232. In this embodiment, the cover plate 23 is a transparent material, for example, a glass material or a silicon material. However, in other applications, the cover plate 23 may also be a non-transparent material.

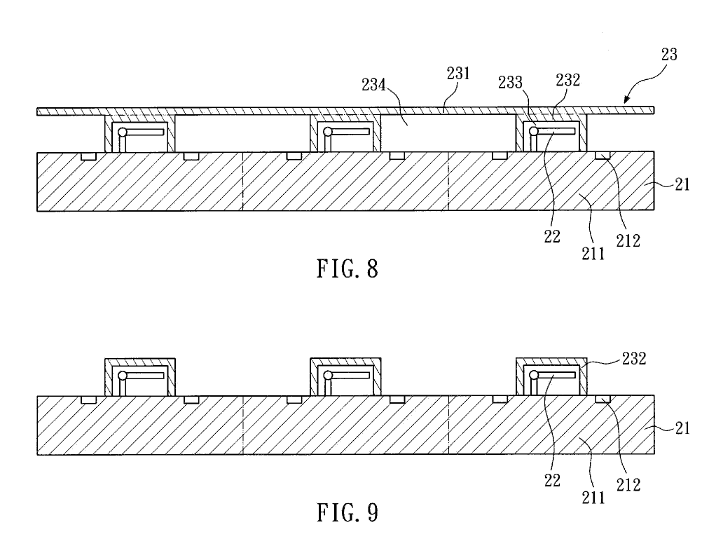

Then, the body 231 is removed. Referring to FIG. 9, in this embodiment, the body 231 is removed by using the grinding process, but the present invention is not limited to using the grinding process to remove the body 231. Other processes may also be used (for example, cuffing process, etching process, or photolithography technique, etc.). It should be noted that after the body 231 is removed, a part of the cover unit 232 at the corresponding position on the first recess 233 can be further removed according to different demands, so as to control the height of the cover unit 232.

It should be noted that, the cover plate 23 is not required to be decomposed into the body 231 and the cover units 232, that is, the cover plate 23 may be integrally formed to have a structure formed by a plurality of first recesses 233 and a plurality of second recesses 234. The first recesses 233 are used to seal the corresponding MEMS 22, and the second recesses 234 are corresponding to the pads 212 of the substrate unit 211. The first recess 233 has a first depth, and the second recess 234 has a second depth. The first depth is smaller than the second depth. Similarly, a part of the cover plate 23 may be removed by using the grinding process or other processes (for example, cutting process, etching process, or photolithography technique, etc) to keep the MEMS 22 sealed in the first recesses 233 and to expose the pads 212 of the substrate unit 211. Furthermore, after the step of removing a part of the cover plate 23, a part of the cover plate 23 at the corresponding position on the first recess 233 can be further removed, so as to reduce the overall thickness.

Referring to FIG. 10, finally, a cutting tool (not shown) is used to cut the substrate 21 according to the edge of the substrate units 211, so as to form a plurality of semiconductor package structures 2. Each semiconductor package structure 2 has a substrate unit 211, a MEMS 22, and a cover unit 232. The semiconductor package structure 2 is the semiconductor package structure having MEMS of the present invention. The semiconductor package structure 2 can be electrically connected to external circuits or external elements by using the pads 212 of the substrate unit 211.

The manufacturing method of the present invention uses the grinding process to remove the body 231, so as to separate the cover units 232, and thus, it is not necessary to pattern the cover plate 23 and the substrate 21 in advance to form the aligning marks to serve as the reference for cutting the cover plate 23 and the substrate 21. Therefore, the packaging process of the present invention is simpler than the conventional packaging process. In addition, as for the manufacturing method of the present invention, it does not need to pattern the cover plate 23 and the substrate 21 in advance to form the aligning cutting marks. Therefore, the cover plate 23 can be transparent material or non-transparent material, so that various materials can be used in various applications. Furthermore, the body 231 may be removed by using the simple grinding process, such that the manufacturing method of the present invention is simpler and quicker, the manufacturing capacity is increased, and the manufacturing cost is reduced.

While the embodiments of the present invention have been illustrated and described, various modifications and improvements can be made by those skilled in the art. The embodiments of the present invention are therefore described in an illustrative but not restrictive sense. It is intended that the present invention may not be limited to the particular forms as illustrated, and that all modifications that maintain the spirit and scope of the present invention are within the scope as defined in the appended claims.

What is claimed is:

1. A method for manufacturing a semiconductor package structure having Micro-Electro-Mechanical Systems (MEMS), comprising:
(a) providing a substrate having a plurality of substrate units, wherein each substrate unit has a plurality of pads;
(b) disposing a MEMS on each substrate unit;
(c) disposing a cover plate on the substrate, wherein the cover plate has a body and a plurality of cover units disposed on a surface of the body, and each cover unit is used for sealing the corresponding MEMS, and the pads of the substrate unit are located outside of the cover unit;
(d) removing the body; and
(e) cutting the substrate to form a plurality of semiconductor package structures, wherein each semiconductor package structure has the substrate unit, the MEMS, and the cover unit.

2. The manufacturing method according to claim 1, wherein the substrate is a CMOS wafer.

3. The manufacturing method according to claim 1, wherein the cover unit has a first recess, the neighboring cover units define a second recess, and the depth of the second recess is greater than that of the first recess.

4. The manufacturing method according to claim 1, wherein the MEMS is an optical device.

5. The manufacturing method according to claim 4, wherein the optical device comprises at least one micro lens set, and each micro lens set comprises:
a supporting component, having a first end and a second end, wherein the second end is located on the substrate;
a hinge, disposed on the first end of the supporting component; and
a micro lens, having one end connected to the hinge, such that the micro lens rotates with the hinge as a center.

6. The manufacturing method according to claim 1, wherein the cover plate is a transparent material.

7. The manufacturing method according to claim 6, wherein the cover plate is a glass or silicon material.

8. The manufacturing method according to claim 1, wherein the cover plate is a non-transparent material.

9. The manufacturing method according to claim 1, wherein, in Step (d), the body is removed by using a process selected from a group comprising grinding process, etching process and photolithography technique.

10. The manufacturing method according to claim 3, further comprising a step of removing a part of the cover unit at a corresponding position on the first recess after Step (d), so as to control the height of the semiconductor package structure.

11. A method for manufacturing a semiconductor package structure having MEMS, comprising:
(a) providing a substrate having a plurality of substrate units, wherein each substrate unit has a plurality of pads;
(b) disposing a MEMS on each substrate unit;
(c) disposing a cover plate on the substrate, wherein the cover plate has a plurality of first recesses and a plurality of second recesses, the first recesses seal the corresponding MEMS, the second recesses are corresponding to the pads of the substrate unit, the first recess has a first depth, the second recess has a second depth, and the first depth is smaller than the second depth;
(d) removing a part of the cover plate, and keeping the MEMS being sealed in the first recesses and exposing the pads of the substrate unit; and
(e) cutting the substrate to form a plurality of semiconductor package structures, wherein each semiconductor package structure has the substrate unit, the MEMS, and a part of the cover plate for defining the first recess.

12. The manufacturing method according to claim 11, wherein the substrate is a CMOS wafer.

13. The manufacturing method according to claim 11, wherein the MEMS is an optical device.

14. The manufacturing method according to claim 13, wherein the optical device comprises at least one micro lens set, and each micro lens set comprises:
a supporting component, having a first end and a second end, wherein the second end is located on the substrate;
a hinge, disposed on the first end of the supporting component; and
a micro lens, having one end connected to the hinge, such that the micro lens rotates with the hinge as a center.

15. The manufacturing method according to claim 11, wherein the cover plate is a transparent material.

16. The manufacturing method according to claim 15, wherein the cover plate is a glass or silicon material.

17. The manufacturing method according to claim 11, wherein the cover plate is a non-transparent material.

18. The manufacturing method according to claim 11, wherein, in Step (d), a part of the cover plate is removed by using a process selected from a group comprising grinding process, etching process and photolithography technique.

19. The manufacturing method according to claim 11, further comprising a step of removing a part of the cover plate at the corresponding position on the first recess after Step (d), so as to control the height of the semiconductor package structure.
